(19) United States
(12) Patent Application Publication
(10) Pub. No.: US 2025/0306653 A1
(43) Pub. Date: Oct. 2, 2025

(54) SYSTEMS AND METHODS FOR CLOSED LOOP THERMAL CONTROL WITH MULTIPLE TEMPERATURE SENSORS

(71) Applicant: Dell Products L.P., Round Rock, TX (US)

(72) Inventors: Rama R. BISA, Bangalore (IN); Deepthi Shree BHAT, Bangalore (IN); Pavan Kumar GAVVALA, Bangalore (IN); Rimple Vijay PANJWANI, Bengaluru (IN)

(73) Assignee: Dell Products L.P., Round Rock, TX (US)

(21) Appl. No.: 18/616,384

(22) Filed: Mar. 26, 2024

(51) Int. Cl. G06F 1/20; H05K 7/20

(52) U.S. Cl. CPC G06F 1/206; H05K 7/20136; H05K 7/20209

(57) ABSTRACT

An information handling system may include a plurality of temperature sensors, each temperature sensor configured to generate a respective temperature measurement, an air mover configured to drive air to cool the information handling system, and a thermal control system for controlling the air mover. The thermal control system may be configured to receive the respective temperature measurements from the plurality of temperature sensors, consume all the available sensor data, select the one with lowest margin based on its maximum temperature value, and select a selected temperature measurement from the respective temperature measurements for temperature-based closed loop control of the thermal control system, and generate a control signal for controlling a speed of the air mover based on the selected temperature measurement.

### TECHNICAL FIELD

The present disclosure relates in general to information handling systems, and more particularly to providing an efficient and optimized approach for closed loop thermal control with multiple temperature sensors.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Temperature control in an information handling system with air movers often involves use of multiple closed-loop feedback systems that alter air mover speed in response to a sensed temperature in the information handling system. For example, using existing approaches, a plurality of closed-loop feedback loops may be used, in which each determines a minimum fan speed based on a sensed temperature, and the maximum of all such fan speeds is selected as the speed for the fan(s). The use of multiple feedback loops adds computational complexity and adds limitations of the number of sensors or sensor data that can be consumed. Further, the use of these limited sensors typically requires manual entries into the power budget table to identify the sensors which should be used for calculating the air mover speed.

### SUMMARY

In accordance with the teachings of the present disclosure, the disadvantages and problems associated with optimizing air mover speed in an information handling system may be substantially reduced or eliminated.

In accordance with embodiments of the present disclosure, an information handling system may include a plurality of temperature sensors, each temperature sensor configured to generate a respective temperature measurement, an air mover configured to drive air to cool the information handling system, and a thermal control system for controlling the air mover. The thermal control system may be configured to receive the respective temperature measurements from the plurality of temperature sensors, select a selected temperature measurement from the respective temperature measurements for temperature-based closed loop control of the thermal control system, and generate a control signal for controlling a speed of the air mover based on the selected temperature measurement.

In accordance with these and other embodiments of the present disclosure, a method may include receiving respective temperature measurements from each of a plurality of temperature sensors, selecting a selected temperature measurement from the respective temperature measurements for temperature-based closed loop control of a thermal control system for controlling an air mover, and generating a control signal for controlling a speed of the air mover based on the selected temperature measurement.

In accordance with these and other embodiments of the present disclosure, a thermal control system may include an output for communicating a control signal for regulating an air speed of an air mover and logic. The logic may be configured to receive respective temperature measurements from each of a plurality of temperature sensors, select a selected temperature measurement from the respective temperature measurements for temperature-based closed loop control of the thermal control system for controlling the air mover, and generate the control signal based on the selected temperature measurement.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIG. 2 illustrates a block diagram of selected components of an example air mover control system, in accordance with the present disclosure.

### DETAILED DESCRIPTION

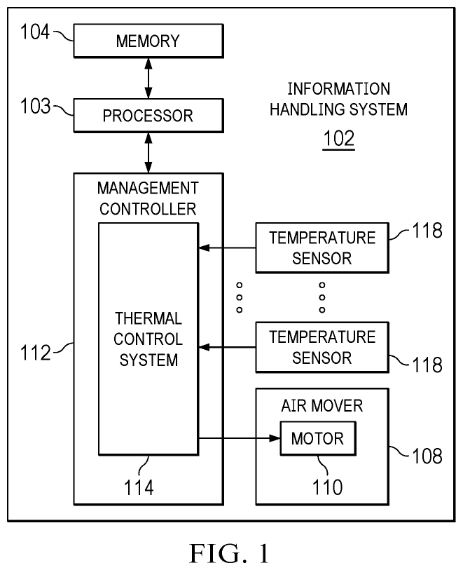

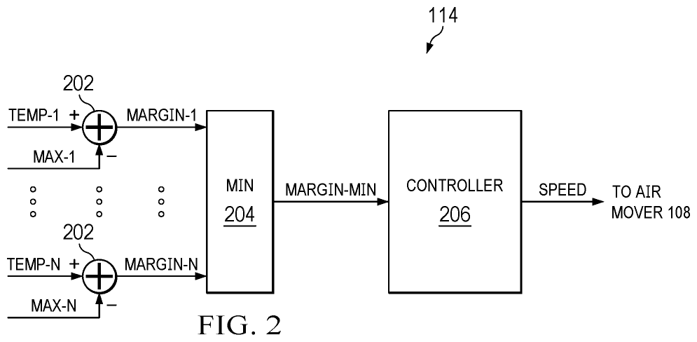

Preferred embodiments and their advantages are best understood by reference to FIGS. 1 and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages, electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, an air mover 108, a management controller 112, and a plurality of temperature sensors 118.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a Personal Computer Memory Card International Association (PCMCIA) card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and which may change the direction of the airflow). In these and other embodiments, rotating and other moving components of air mover 108 may be driven by a motor 110. The rotational speed of motor 110 may be controlled by an air mover control signal (e.g., a pulse-width modulation signal) communicated from thermal control system 114 of management controller 112. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources. Example functionality of thermal control system 114 is set forth in greater detail with respect to the discussion of FIG. 2, below.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118), and based on such signals, calculate an air mover driving signal (e.g., a pulse-width modulation signal) to maintain an appropriate level of cooling, increase cooling, or decrease cooling, as appropriate, and communicate such air mover driving signal to air mover 108. Thermal control for air mover 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air mover 108, for example, as described in U.S. Pat. No. 11,350,543, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A temperature sensor 118 may be any system, device, or apparatus (e.g., a thermometer, thermistor, etc.) configured to communicate a signal to thermal control system 114 indicative of a temperature within information handling system 102. In some embodiments, the plurality of temperature sensors 118 may be spread throughout different locations in information handling system 102. In other embodiments, the plurality of temperature sensors 118 may be located on the same information handling resource (e.g., as multiple sensors on a channel card).

In addition to processor 103, memory 104, air mover 108, management controller 112, and plurality of temperature sensors 118, information handling system 102 may include one or more other information handling resources. In addition, for the sake of clarity and exposition of the present disclosure, FIG. 1 depicts only one air mover 108. In embodiments of the present disclosure, information handling system 102 may include any number of air movers 108.

FIG. 2 illustrates a block diagram of selected components of an example temperature control system 114, in accordance with the present disclosure. As shown in FIG. 2, temperature control system 114 may comprise a plurality of summers 202, a minimum detection control block 204, and a controller 206.

Each summer 202 may receive a respective measured temperature (e.g., TEMP-1, . . . , TEMP-N) from a respective temperature sensor 118 and a respective maximum temperature (e.g., MAX-1, . . . , MAX-N) for such temperature sensor 118, and generate a respective margin value (e.g., MARGIN-1, . . . , MARGIN-N) for such temperature sensor 118 as the difference between the respective measured temperature and maximum temperature values.

Minimum detection control block 204 may comprise any suitable system, device, or apparatus configured to receive the plurality of margin values associated with the various temperature sensors 118 (e.g., MARGIN-1, MARGIN-N) and may select the margin having the smallest value (e.g., associated with the temperature sensor having a temperature closest to its maximum value) as the margin value MARGIN-MIN used to determine a speed for air mover 108.

Controller 206 may comprise any suitable system, device, or apparatus configured to receive a margin value (e.g., margin value MARGIN-MIN) and based on such margin value, generate a speed signal SPEED indicative of a speed for motor 110 of air mover 108.

For example, in some embodiments, controller 206 may use temperature margin feedback to correlate a margin to a particular speed in accordance with a lookup table (e.g., a table, map, database, or other data structure) that associates one or more measured temperatures to corresponding air mover setpoint velocities. Such lookup table may be created by characterization of the thermal system during development of information handling system 102, by way of an in-system characterization routine. In some embodiments, such direct conversion controller 202 may be fine-tuned or adapted with a cooling profile suitable for use with a component (e.g., a processor) having an acoustic heat sink. Such an acoustic heat sink may conduct heat away from a component more efficiently than a standard heat sink (e.g., may have greater surface area than a standard heat sink), and thus may allow air mover 108 to operate at lower speeds for motor 110, thus minimizing acoustic noise generated by air mover 108.

In addition or alternatively, in some embodiments, a controller 206 may comprise a proportional-integral-differential (PID) controller, a proportional-integral (PI) controller, a proportional-differential (PD) controller, or other similar type controller that generates a signal indicative of a speed for motor 110 of air mover 108 in order to maximize the temperature margin.

The methods and systems disclosed herein may have one or more advantages over traditional approaches. For example, the approaches disclosed herein are independent and may not require a dependency on a power budget table of information handling system 102 to define the indicative sensors for calculating an air mover speed. Also, the approaches disclosed herein allow for the consideration of data from multiple sensors, but with the advantage of not requiring a computationally-expensive control loop for each sensor.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a plurality of temperature sensors, each temperature sensor configured to generate a respective temperature measurement;
an air mover configured to drive air to cool the information handling system; and
a thermal control system for controlling the air mover and configured to:
receive the respective temperature measurements from the plurality of temperature sensors;
select a selected temperature measurement from the respective temperature measurements for temperature-based closed loop control of the thermal control system; and
generate a control signal for controlling a speed of the air mover based on the selected temperature measurement.

2. The information handling system of claim 1, wherein the thermal control system is further configured to:
compare each of the respective temperature measurements to a respective maximum temperature to determine a respective temperature margin for each of the respective temperature measurements;
select a minimum temperature margin from all of the respective temperature margins; and
generate the control signal based on the minimum temperature margin.

3. A method comprising:
receiving respective temperature measurements from each of a plurality of temperature sensors;
selecting a selected temperature measurement from the respective temperature measurements for temperature-based closed loop control of a thermal control system for controlling an air mover; and
generating a control signal for controlling a speed of the air mover based on the selected temperature measurement.

4. The method of claim 3, further comprising:
comparing each of the respective temperature measurements to a respective maximum temperature to determine a respective temperature margin for each of the respective temperature measurements;
selecting a minimum temperature margin from all of the respective temperature margins; and
generating the control signal based on the minimum temperature margin.

5. A thermal control system comprising:
an output for communicating a control signal for regulating an air speed of an air mover; and
logic configured to:
receive respective temperature measurements from each of a plurality of temperature sensors;
select a selected temperature measurement from the respective temperature measurements for temperature-based closed loop control of the thermal control system for controlling the air mover; and
generate the control signal based on the selected temperature measurement.

6. The thermal control system of claim 5, wherein the logic is further configured to:
compare each of the respective temperature measurements to a respective maximum temperature to determine a respective temperature margin for each of the respective temperature measurements;
select a minimum temperature margin from all of the respective temperature margins; and
generate the control signal based on the minimum temperature margin.

7. An article of manufacture comprising:
a non-transitory computer-readable medium; and
computer-executable instructions carried on the computer-readable medium, the instructions readable by a processor, the instructions, when read and executed, for causing the processor to:
receive respective temperature measurements from each of a plurality of temperature sensors;
select a selected temperature measurement from the respective temperature measurements for temperature-based closed loop control of a thermal control system for controlling an air mover; and
generate a control signal for controlling a speed of the air mover based on the selected temperature measurement.

8. The article of claim 7, the instructions for further causing the processor to:
compare each of the respective temperature measurements to a respective maximum temperature to determine a respective temperature margin for each of the respective temperature measurements;
select a minimum temperature margin from all of the respective temperature margins; and
generate the control signal based on the minimum temperature margin.
